(19) United States
(12) Patent Application Publication
(10) Pub. No.: US 2025/0218654 A1
(43) Pub. Date: Jul. 3, 2025

(54) NO-ARC ON-LOAD TAP CHANGER, SWITCHING CONTROL METHOD AND ELECTRICAL EQUIPMENT

(71) Applicant: Xiaoming LI, Jinan (CN)

(72) Inventor: Xiaoming LI, Jinan (CN)

(21) Appl. No.: 18/835,207

(22) PCT Filed: Feb. 16, 2023
(86) PCT No.: PCT/CN2023/076537

§ 371 Date: Aug. 1, 2024

(30) Foreign Application Priority Data
Mar. 9, 2022 (CN) 202210232941.2

(51) Int. Cl. H01F 29/04; H03K 17/72

(52) U.S. Cl. CPC H01F 29/04; H03K 17/72

(57) ABSTRACT

A no-arc on-load tap changer, a switching control method and electrical equipment, including at least two main switches, two change-over switches and two thyristor auxiliary modules; the two thyristor auxiliary modules are connected in parallel with originally-closed main switch or to-be-closed main switch according to required time sequence during switching of main switch; the main switches and change-over switches are rotary-shaft-type switches, dynamic contacts of main switches and change-over switches are arranged on rotary shaft, static contacts of corresponding main switches and change-over switches are connected to corresponding transformer taps, and dynamic contacts are connected with coaxial static contacts during rotating along with the rotary shaft; all switches are controlled to be broken/closed according to the preset time sequence, realizing transfer of load current from the originally-closed main switch to the to-be-closed main switch without interruption, and no arc in breaking/closing processes.

The present invention claims priority benefits to Chinese Patent Application number 202210232941.2, entitled “a no-arc on-load tap changer, switching control method and electrical equipment”, filed on Mar. 9, 2022, with the China National Intellectual Property Administration (CNIPA), the entire contents of which are incorporated herein by reference.

### TECHNICAL FIELD

The present invention belongs to the technical field of power transmission and transformation of power systems, and particularly relates to a no-arc on-load tap changer, a switching control method and electrical equipment.

### BACKGROUND

The statements in this section merely provide background information related to the present invention and do not necessarily constitute prior art.

Under the condition that the transformer has load current (on-load), it is necessary to use an on-load tap changer to switch the tap of one voltage of the transformer to the tap of another voltage, and to ensure that the power user does not lose power during the switching process. Wherein, the on-load tap changer refers to a voltage regulating device suitable for operating under transformer excitation or load and used to change the tap connection position of transformer windings, and the basic principle thereof is to realize the switching between the transformer winding taps without interrupting the load current, so as to change the number of turns of the winding, that is, the voltage ratio of the transformer, and finally realize the purpose of voltage regulation.

The resistance transition mode is generally adopted in the existing on-load tap changer to realize the switching process of two different voltage taps. However, the resistance transition mode has the defect of radian in the switching process.

Chinese application number CN2012105791965, CN2013105976862 and CN2014102602640 respectively introduced different no-arc on-load tap changers, but since the oil-immersed on-load tap changer is suitable to be driven by a rotary shaft, and the inventors have found that, the devices proposed in the above patents are mainly used in circuits composed of contactors or relay contacts, while the no-arc on-load tap changers composed of contactors or relays are not suitable for using in oil immersed transformers.

An on-load tap changer in the solution of the on-load tap changer provided in the Chinese application number CN2018102904704 has a structure driven by a rotary shaft, however, the inventor found that this patent is still complicated in operating structure because various switches are distributed on two or three rotary shafts which are not synchronized, so that when one rotary shaft needs to rotate, the other rotary shaft needs to be stationary; moreover, it lacks a coordination control mechanism between rotary shafts, a matching scheme between dynamic contacts and static contacts of rotary shafts, and a driving scheme for controlling switches.

### SUMMARY

In order to solve the technical problems existing in the background, the present invention provides a no-arc on-load tap changer, a switching control method, and electrical equipment, wherein the no-arc on-load tap changer is suitable for an oil-immersed transformer driven by a rotary shaft, and has the advantages of simple operation structure and less time for a complete switching process.

In order to achieve the above object, the present invention adopts the following technical solution.

A first aspect of the present invention provides a no-arc on-load tap changer.

In one or more embodiments, providing a first type of structure of the no-arc on-load tap changer, including at least two main switches, two change-over switches and two thyristor auxiliary modules; wherein, each of the two thyristor auxiliary modules includes two control switches; the two main switches include an originally-closed main switch and a to-be-closed main switch; the two main switches are connected in corresponding loops of a voltage regulating coil through taps of corresponding transformers; the two thyristor auxiliary modules are connected in parallel with the originally-closed main switch or the to-be-closed main switch according to a required time sequence during a switching process of main switch;
the two main switches and the two change-over switches are all rotary-shaft-type switches, dynamic contacts of the two main switches and dynamic contacts of the two change-over switches are all arranged on a rotary shaft, static contacts respectively corresponding to the two main switches and the two change-over switches are connected to the taps of the corresponding transformers, and the dynamic contacts are connected with coaxial static contacts in a process of rotating along with the rotary shaft; wherein, according to a preset time sequence, controlling corresponding ones of the two main switches, corresponding ones of the two change-over switches, and corresponding ones of the control switches to be broken and closed, to realize that a load current is transferred from the originally-closed main switch to the to-be-closed main switch without interruption, and no arc in the breaking and closing process of each of the two main switches, the two change-over switches, and the control switches.

As an implementation mode, a first end of the each of the two thyristor auxiliary modules is suspended or connected in parallel with the originally-closed main switch before carrying out the switching process of main switch, and a voltage at both ends of the each of the two thyristor auxiliary modules is zero.

As an implementation mode, each of the control switches is also a rotary-shaft-type switch, and dynamic contacts of the control switches are also arranged on the rotary shaft.

As an implementation mode, all the static contacts of the two main switches and the two change-over switches are divided into at least two groups, each of the two groups of the static contacts is correspondingly mounted on a track, and the two tracks are centered on the rotary shaft and fixed.

As an implementation mode, a number of the static contacts in the each of the two groups of the static contacts are the same.

As an implementation mode, the static contacts in the each of the two groups of the static contacts are mounted on the two tracks with equal radians.

As an implementation mode, when all the static contacts of the two main switches and the two change-over switches are divided into the two groups, relationships of radians of the static contacts on corresponding one of the two tracks are:

$$\begin{matrix}0 < Δ W < W 1 < 0.5 W < W 2 , \\ Δ W = ( W - W 2 ) ,\end{matrix}$$

wherein: W and W1 respectively are radians between center positions of the static contacts and radians of the static contacts on a first track of the two tracks, W2 and ΔW respectively are radians of the static contacts and radians of gaps between the static contacts on a second track of the two tracks.

As an implementation mode, before the switching process of main switch, a normal operating state of the no-arc on-load tap changer is:
one of the dynamic contacts on the rotary shaft is located on a center line of one of the static contacts, and remaining the dynamic contacts are respectively located on center lines of gaps between the static contacts.

As an implementation mode, when three the dynamic contacts are provided on the rotary shaft, a first dynamic contact of the three dynamic contacts and a second dynamic contact of the three dynamic contacts respectively are arranged on each side of a third dynamic contact of the three dynamic contacts, then relationships of radians between the three dynamic contacts are:

$$\begin{matrix}0 < Δ W < {W}_{1 dynamic} < 0.5 W < {W}_{2 dynamic} \\ Δ {W}_{dynamic} = ( W - {W}_{2 dynamic} )\end{matrix}$$

Wherein W is the radian between the center positions of the static contacts on the first track, W_{1dynamic} and W_{2dynamic} respectively are the radian of the first dynamic contact and the second dynamic contact, ΔW_{dynamic} is the radian of the gap between the first dynamic contact and the second dynamic contact.

As an implementation mode, the radians of the static contacts are greater than the radians of the dynamic contacts.

As an implementation mode, the radians of the static contacts are less than or equal to the radians of the dynamic contacts.

As an implementation mode, the breaking and closing of the control switch is controlled by a control mechanism.

As an implementation mode, the control mechanism is of a mechanical linkage mechanism.

As an implementation mode, the mechanical linkage mechanism includes a deflection shaft, wherein the deflection shaft is fixed on a rotary shaft and rotates along with the rotary shaft; a lever arm and a spring arm which can rotate around the deflection shaft are mounted on the deflection shaft; one end of the spring arm is provided with a contact; and the contact makes contact with or detached from corresponding ones of the control switches along with rotation of the rotary shaft, so that the corresponding ones of the control switches are broken and closed, respectively.

As an implementation mode, a control means for the control mechanism is realized by driving the change-over switches by the rotary shaft.

As an implementation mode, the structure of the two thyristor auxiliary modules is same.

As an implementation mode, the structure of the each of the two thyristor auxiliary modules comprises a pair of thyristors connected in reverse parallel; an RC series circuit is connected in parallel at two ends of the pair of the thyristors; a capacitor, a resistor and a diode are sequentially connected between a gate electrode and a cathode of each thyristor of the pair of the thyristors; an anode of the diode is connected with the cathode of corresponding one of the pair of the thyristors, and a cathode of the diode is connected with the gate electrode of the corresponding one of the pair of the thyristors; the gate electrodes of the pair of the thyristors are connected in series with one of the two control switches through a full-bridge rectifier circuit; two voltage-stabilizing tubes, a resistor, and another one of the two control switches are connected in series between the gate electrodes of the two the reverse-parallel-connected thyristors; wherein the two voltage-stabilizing tubes are connected in reverse series, the two voltage-stabilizing tubes are connected in series with the resistor and then connected with an output end of the full-bridge rectifier circuit, cathodes of the two voltage-stabilizing tubes corresponds to an anode output end of the full-bridge rectifier circuit, and anodes of the two voltage-stabilizing tubes corresponds to a cathode output end of the full-bridge rectifier circuit.

The present invention further provides a second type of structure of the no-arc on-load tap changer, including at least two main switches, two change-over switches and two thyristor auxiliary modules; wherein, each of the two thyristor auxiliary modules includes two control switches; the two main switches include an originally-closed main switch and a to-be-closed main switch; the two main switches are connected in corresponding loops of a voltage regulating coil through taps of corresponding transformers; the two thyristor auxiliary modules are connected with the originally-closed main switch or the to-be-closed main switch according to a required time sequence during the switching process of main switch.

The two main switches and the two change-over switches are all rotary-shaft-type switches, wherein the two main switches and corresponding ones of the two change-over switches are linked and synchronously rotated, respectively; corresponding main switches, change-over switches, and control switches are controlled to be broken and closed according to the preset time sequence, to realize that the load current is transferred from the originally-closed main switch to the to-be-closed main switch without interruption, and no arc in the breaking and closing process of each of the switches.

As an implementation mode, the control mechanism is of a mechanical linkage mechanism.

As an implementation mode, the mechanical linkage mechanism includes a deflection shaft, wherein the deflection shaft is fixed on a rotary shaft and rotates along with the rotary shaft; a lever arm and a spring arm which can rotate around the deflection shaft are mounted on the deflection shaft; one end of the spring arm is provided with a contact; and the contact makes contact with or detach from a corresponding control switch along with rotation of the rotary shaft, so that the corresponding control switch is broken and closed.

As an implementation mode, the control means of the control mechanism is realized by driving change-over switches by the rotary shaft.

As an implementation mode, the structure of the two thyristor auxiliary modules is same.

As an implementation mode, each of the two thyristor auxiliary module includes a pair of thyristors connected in reverse parallel; an RC series circuit is connected in parallel at two ends of the reverse-parallel-connected thyristors; a capacitor, a resistor and a diode are sequentially connected between a gate electrode and a cathode of each of the reverse-parallel-connected thyristors; an anode of the diode is connected with the cathode of the corresponding one of the reverse-parallel-connected thyristors, and a cathode of the diode is connected with the gate electrode of the corresponding one of the reverse-parallel-connected thyristors; the gate electrodes of the two the reverse-parallel-connected thyristors are connected in series with one of the two control switches through a full-bridge rectifier circuit; two voltage-stabilizing tubes, a resistor, and another one of the two control switches are connected in series between gate electrodes of the two the reverse-parallel-connected thyristors; wherein the two voltage-stabilizing tubes are connected in reverse series; the two voltage-stabilizing tubes are connected in series with the resistor and then connected with an output end of the full-bridge rectifier circuit; cathodes of the two voltage-stabilizing tubes corresponds to an anode output end of the full-bridge rectifier circuit; and anodes of the two voltage-stabilizing tubes corresponds to a cathode output end of the full-bridge rectifier circuit.

A second aspect of the present invention provides as witching control method for a no-arc on-load tap changer.

In one or more embodiments, the present invention provides a first type of the switching control method for the no-arc on-load tap changer, including:
controlling a rotation of the rotary shaft to drive the dynamic contacts to be connected with or detached from corresponding ones of the static contacts;
controlling corresponding ones of the main switches, corresponding ones of the change-over switches, and corresponding ones of the control switches to be broken and closed according to the preset time sequence, to realize that the load current is transferred from the originally-closed main switch to the to-be-closed main switch without interruption, and no arc in the breaking and closing processes of all the switches.

As an implementation mode, a rotation mode of the rotary shaft includes a clockwise rotation and a counterclockwise rotation.

As an implementation mode, the process of one-time switching of main switch, including:
dynamic contacts of corresponding one of the two change-over switches contact with corresponding static contacts to close a first control switch of the thyristor auxiliary module connected with the originally-closed main switch, and breaking the originally-closed main switch;
closing a second control switch of the thyristor auxiliary module connected to the to-be-closed main switch and breaking the first control switch of the thyristor auxiliary module connected to the originally-closed main switch;
after a set time interval, closing a first control switch of the thyristor auxiliary module connected with the to-be-closed main switch, and closing the to-be-closed main switch; and
breaking all the control switches, and the dynamic contacts of the corresponding one of the two change-over switches are detached from the corresponding static contacts to complete the one-time switching of main switch.

As an implementation mode, before the switching of main switch, voltages between two ends of each of the two thyristor auxiliary modules are made to zero.

The present invention further provides a second type of the switching control method for the no-arc on-load tap changer, including:
controlling breakings and closings of the corresponding main switches and change-over switches by linking and synchronously rotating;
controlling corresponding main switches, change-over switches, and control switch to be broken and closed according to the preset time sequence, to realize that the load current is transferred from an originally-closed main switch to a to-be-closed main switch without interruption, and no arc in the breaking and closing processes of each of the switches.

A third aspect of the present invention provides an electric accessory.

In one or more embodiments, the electric accessory includes:
a voltage regulating coil, including a plurality of transformer taps; and
a no-arc on-load tap changer, being connected to the voltage regulating coil;
wherein the no-arc on-load tap changer is any one of the no-arc on-load tap changers described above.

Compared with the prior art, the present invention has the advantages that:
(1) The no-arc on-load tap changer provided by the present invention solves the problem that the existing no-arc on-load tap changer is not suitable for oil-immersed transformers by mounting the dynamic contacts on a rotary shaft and turning on with the corresponding static contacts along with the rotation of the rotary shaft. The no-arc on-load tap changer of the present invention adopts the rotary shaft as a driving power, and finally controls the originally-closed main switch, the change-over switches, the control switches and the to-be-closed main switch to perform matched breaking and closing according to preset time sequence, so as to realize no-arc switching and switching among the main switches in the breaking and closing process, and various switches and contacts can be operated in the oil tank of the oil-immersed transformer.
(2) The no-arc on-load tap changer provided by the present invention, can be realized on the basis of the basic structure of the existing oil-immersed on-load tap changer, also, can be realized on the basis of the basic structure of the existing oil-immersed on-load tap changer.
(3) The no-arc on-load tap changer provided by the present invention, the change-over switch includes a plurality of static contacts, the corresponding static contacts of the change-over switch are connected to the transformer tap, at least one control switch is mounted on the rotary shaft, and the breaking and closing thereof are controlled by the rotary shaft, so that the oil-immersed vacuum on-load tap changer can be upgraded on the basis of the basic structure of the existing oil-immersed vacuum on-load tap changer, and the switching between the main switches and no radian in the breaking and closing process can be realized.
(4) The no-arc on-load tap changer provided by the present invention, retains the accumulated experience in the past, simplifies the structure, reduces the volume, the weight, and the cost, has the benefits of small operating vibration, low failure rate, and short time of one-time complete switching process.

Advantages of additional aspects of the present invention will be set forth in part in the following description, and in part will become apparent from the following description, or may be learned by practice of the present invention.

### BRIEF DESCRIPTION OF THE DRAWINGS

The accompanying drawings constituting a part of the present invention are used to provide a further understanding of the present invention. The exemplary examples of the present invention and descriptions thereof are used to explain the present invention, and do not constitute an improper limitation of the present invention.

FIG. 1 is a circuit diagram of a thyristor auxiliary module according to one embodiment of the present invention;

FIG. 2 is a structure diagram of a rotary shaft of a first-type no-arc on-load tap changer according to one embodiment of the present invention;

FIG. 3 is a horizontal expansion structure diagram of the first-type no-arc on-load tap changer according to one embodiment of the present invention;

FIG. 4 is a diagram showing a radian relationship of static contacts according to one embodiment of the present invention;

FIG. 5 is a structural diagram of switches KB1 and KB2 according to one embodiment of the present invention; and

FIG. 6 is a structure diagram of a rotary shaft of a second type of the no-arc on-load tap changer according to one embodiment of the present invention;

In figures: 1, tap I; 2, tap II; 3, tap III; 4, rotary shaft; 5, fixed plate; 6, deflection shaft; 7, lever arm; 8, spring arm; 9, first circular hoop; 10, second circular hoop; 11, switch KB1; 12, switch KB2.

### DETAILED DESCRIPTION

The present invention will now be further described below with reference to the accompanying drawings and embodiments.

It should be pointed out that the following detailed descriptions are all illustrative and are intended to provide further descriptions of the present invention. Unless otherwise specified, all technical and scientific terms used in the present invention have the same meanings as those usually understood by a person of ordinary skill in the art to which the present invention belongs.

It should be noted that the terms used herein are merely used for describing specific implementations, and are not intended to limit exemplary implementations of the present invention. As used herein, the singular form is also intended to include the plural form unless the context clearly dictates otherwise. In addition, it should further be understood that, terms “include” and/or “including” used in this specification indicate that there are features, steps, operations, devices, components, and/or combinations thereof.

### <A No-Arc On-Load Tap Changer and a Switching Control Method Thereof>

In order to solve the problems that the existing no-arc on-load tap changer in the background art is not suitable for an oil-immersed transformer, and even if the no-arc on-load tap changer is suitable for the oil-immersed transformer, various switches are respectively distributed on two or three rotary shafts which are not synchronous, when one rotary shaft needs to rotate, the other rotary shaft needs to be stationary, the operation structure is complex, and a rotary shaft coordination control mechanism, a dynamic contact and a static contact matching scheme of the rotary shaft and a driving scheme for controlling the switch are lacking. To solve the above problems, a no-arc on-load tap changer and a corresponding switching control method are provided by the present invention.

### Embodiment 1

The present embodiment provides a no-arc on-load tap changer, which includes at least two main switches, two change-over switches and two thyristor auxiliary modules; wherein, each of the two thyristor auxiliary modules includes two control switches; that the two main switches comprise an originally-closed main switch and a to-be-closed main switch; the two main switches are connected in corresponding loops of a voltage regulating coil through corresponding transformer taps; the two thyristor auxiliary modules are connected in parallel with the originally-closed main switch or the to-be-closed main switch according to a required time sequence during the switching of main switch;
the two main switches and the two change-over switches are all rotary-shaft-type switches, dynamic contacts of the two main switches and the two change-over switches are arranged on a rotary shaft, static contacts respectively corresponding to the two main switches and the two change-over switches are connected to taps of corresponding transformers, and the dynamic contacts are connected with coaxial static contacts in the process of rotating along with the rotary shaft; according to the preset time sequence, corresponding main switches, change-over switches, and control switches are controlled to be broken and closed, to realize that the load current is transferred from the originally-closed main switch to the to-be-closed main switch without interruption, and no arc in the breaking and closing process of each of the switches.

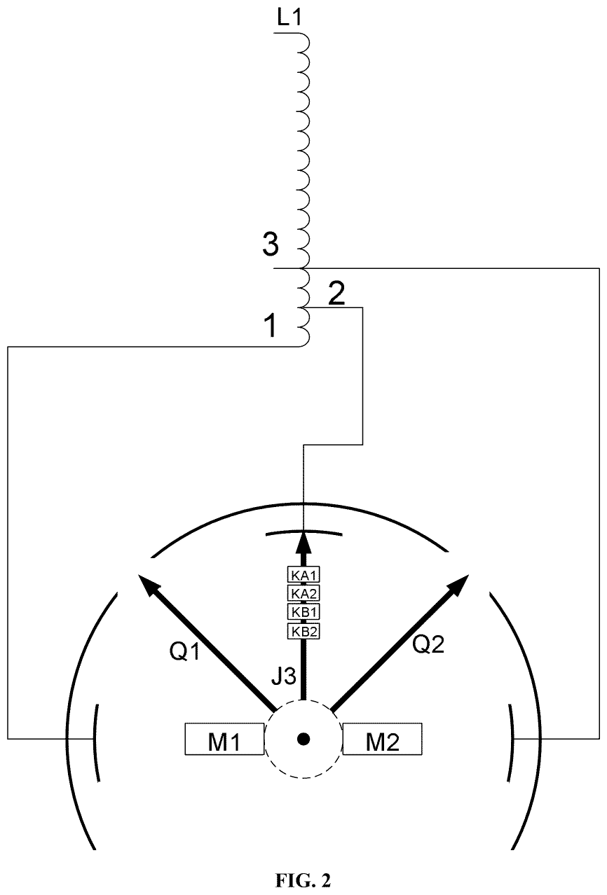

The no-arc on-load tap changer of the present embodiment uses the rotary shaft as power, is suitable for oil-immersed transformers, and the no-arc on-load tap changer is composed of rotating sliding contacts, and a structure thereof is shown in FIG. 2. Because the structure of the oil-immersed on-load tap changer is generally three-phase on-load tap changers mounted on an insulated rotary shaft and the three-phase on-load tap changers have the same structure and are driven synchronously by the rotary shaft. For convenience of description, FIG. 2 takes a single-phase oil-immersed on-load tap changer with three taps as an example.

In the present embodiment, the control switches are also a rotary-shaft-type switch, and the dynamic contacts of the control switches are also arranged on the rotary shaft.

The static contacts of all the main switches and the change-over switches are divided into at least two groups, each of the two groups of the static contacts is correspondingly mounted on one track, and the tracks corresponding to the two groups take a rotary shaft as the center and are fixed; wherein, the tracks are a circular insulating frame, and does not move along with the rotary shaft. The dynamic contacts are mounted on the rotary shaft and rotate along with the rotary shaft.

Wherein, before the switching of the no-arc on-load tap changer, one end of each of the thyristor auxiliary modules is suspended or connected in parallel with the originally-closed main switch. And, before the switching of the no-arc on-load tap changer, the voltages between both ends of the thyristor auxiliary modules are zero.

In a switching process of the no-arc on-load tap changer, the thyristor auxiliary modules are respectively connected in parallel with the originally-closed main switch or the to-be-closed main switch according to a required time sequence.

The present embodiment takes a number of the groups of the static contacts as two, that is, there are two tracks; each of the groups of the static contacts has three static contacts, and the number of the dynamic contacts is three, as an example.

It can be understood that, in other embodiments, a person skilled in the art can specifically set the number of dynamic contacts and the number of the groups of the static contacts according to actual situations.

In the present embodiment, there are three static contacts on the first track, and the three static contacts are arranged in sequence; the radian of the gap between the center positions of the first and second static contacts on the first track is equal to W, and the radian of the gap between the center positions of the second and third static contacts on the first track is also equal to W; there are also static contacts on the second track, and the number of static contacts on the second track is equal to the number of static contacts on the first track; the center line of each static contact on the first track correspondingly overlaps with the center line of each static contact on the second track respectively, and the one of the static contacts on the first track and the one of the static contacts on the second track that with overlapped centerlines are connected and further sequentially connected with the tap I, the tap II and the tap III of the transformer coil L1 respectively.

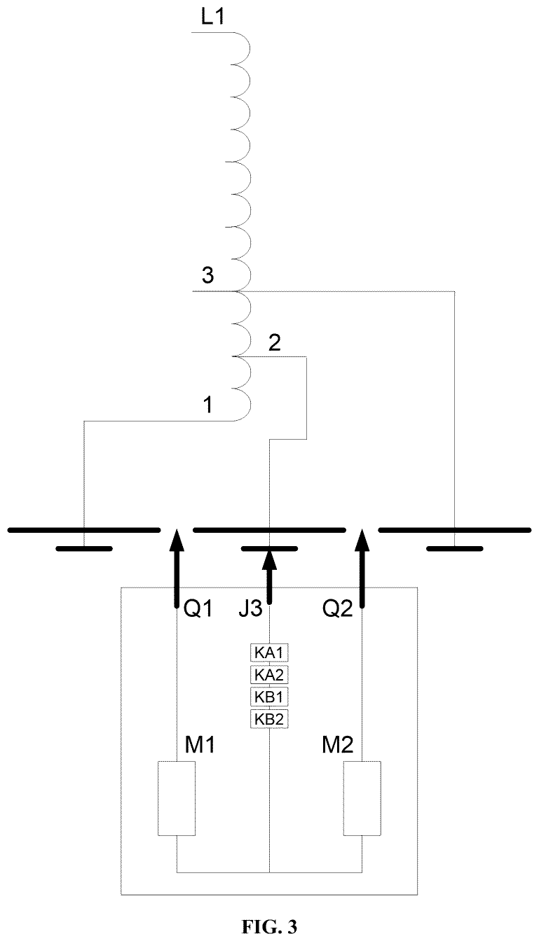

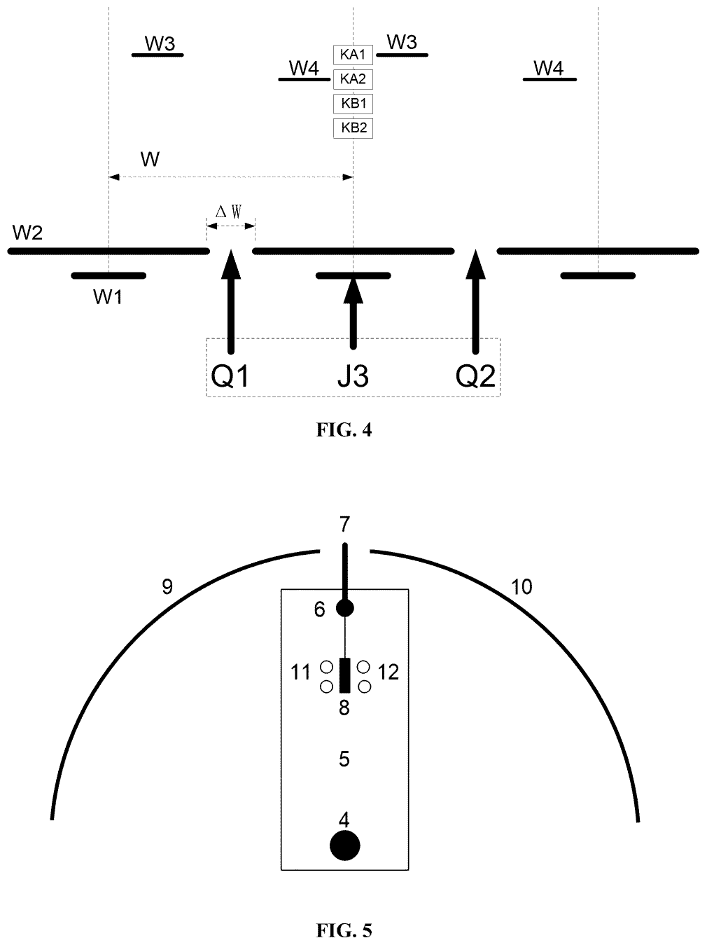

The radians of the three static contacts on the first track are the same, equal to W1; the radians of the three static contacts on the second track are the same, equal to W2; and the radians of the gaps between the static contacts on the second track are the same, equal to ΔW=(W−W2). For convenience of explanation, the structure diagram of the rotary shaft the no-arc on-load tap changer of FIG. 2 is expanded horizontally, as shown in FIGS. 3 and 4. Wherein, let. 0<ΔW<W1<0.5 W<W2.

In the present embodiment, there are three dynamic contacts on the rotary shaft, such as the dynamic contact J3, the dynamic contact Q1 and the dynamic contact Q2; the dynamic contacts are mounted on the rotary shaft to rotate along with the rotary shaft; and the dynamic contact Q1 and the dynamic contact Q2 are respectively arranged on two sides of the dynamic contact J3.

The dynamic contact J3 respectively connected or disconnected with the three static contacts on the first track in turn when rotating along with the rotary shaft, to realize the connection and disconnection of the main switch; when the dynamic contact Q1 and the dynamic contact Q2 respectively connected or disconnected with the three static contacts on the second track in turn when rotating along with the rotary shaft, to realize the conversion of the change-over switch; the center position of the dynamic contact Q1 is on the second track on the left side of the center of the dynamic contact J3, and an included angle there between is 0.5 W; the center position of the dynamic contact Q2 is on the second track on the right side of the center of the dynamic contact J3, and an included angle there between is 0.5 W.

A normal operating state of the no-arc on-load tap changer of the present embodiment before switching is that: the dynamic contact J3 on the rotary shaft is located on the center line of the static contact W1, and the dynamic contact Q1 and the dynamic contact Q2 are respectively located on the center line of the gaps.

In the present embodiment, the thyristor auxiliary module M1 and the thyristor auxiliary module M2 have same a main circuit, and the main circuit of each of the two thyristor auxiliary modules includes a pair of thyristors connected in reverse parallel; an RC series circuit is connected in parallel at two ends of the reverse-parallel-connected thyristors; a capacitor, a resistor and a diode are sequentially connected between a gate electrode and a cathode of each of the reverse-parallel-connected thyristors; an anode of the diode is connected with the cathode of the corresponding one of the reverse-parallel-connected thyristors, and a cathode of the diode is connected with the gate electrode of the corresponding one of the reverse-parallel-connected thyristors; the gate electrodes of the two the reverse-parallel-connected thyristors are connected in series with one of the two control switches through a full-bridge rectifier circuit; two voltage-stabilizing tubes, a resistor, and another one of the two control switches are connected in series between gate electrodes of the two the reverse-parallel-connected thyristors; wherein the two voltage-stabilizing tubes are connected in reverse series; the two voltage-stabilizing tubes are connected in series with the resistor and then connected with an output end of the full-bridge rectifier circuit; cathodes of the two voltage-stabilizing tubes corresponds to an anode output end of the full-bridge rectifier circuit; and anodes of the two voltage-stabilizing tubes corresponds to a cathode output end of the full-bridge rectifier circuit.

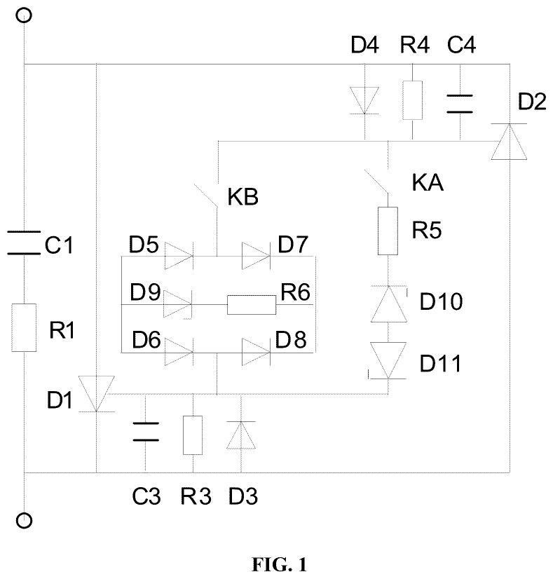

Specifically, as shown in FIG. 1, the main circuit of the each of the thyristor auxiliary modules includes a pair of thyristors D1 and D2 connected in reverse parallel; a resistor R1 connected in series with a capacitor C1 is connected in parallel at both ends of the reverse-parallel-connected thyristors D1 and D2; gates and cathodes of the two thyristors D1 and D2 are respectively connected in parallel with capacitors C3 and C4, resistors R3 and R4, and diodes D3 and D4; wherein, anodes of the diodes D3 and D4 are respectively connected with the cathodes of the thyristors D1 and D2, and cathodes of the diodes D3 and D4 are respectively connected with the gates of the thyristors D1 and D2; voltage-regulator tubes D10 and D11 are connected in reverse series and then connected in series with a resistor R5, and then connected in series with the control switch KA, and then connected between the gate electrodes of the two thyristors D1 and D2. The full-bridge rectifier circuit composed of diodes D5, D6, D7 and D8 is connected between the gate electrodes of the two thyristors D1 and D2 after connecting an input terminal of the full-bridge rectifier circuit in series with the control switch KB, the voltage-regulator tube D9 is connected in series with the resistor R6 and then connected with an output terminal of the full-bridge rectifier circuit, wherein the cathode of the voltage-regulator tube D9 corresponds to the anode output terminal of the full-bridge rectifier circuit, and the anode of the voltage-regulator tube D9 corresponds to the cathode output terminal of the full-bridge rectifier circuit; the stable voltage of voltage regulator tube D9 is U1=k1*U2, wherein k1 is the reliability coefficient, taking a value between 1.2 and 2, U2 is the peak value of the regulated interval voltage of the voltage regulating transformer. It is suggested that the stable voltage of voltage regulator tubes D10 and D11 should be 1-3 volts.

It should be noted that the specific working process of the thyristor auxiliary module has been disclosed in the Chinese application number 201810290470.4, and will not be repeated here.

In the present embodiment, the thyristor auxiliary module M1 is connected to the control switches KA1 and KB1, and the thyristor auxiliary module M2 is connected to the control switches KA2 and KB2.

The dynamic contact J3 is connected with the public endpoint; two ends of the main circuit of the thyristor auxiliary module M1 are connected with the dynamic contact Q1 and the public endpoint, respectively; and two ends of the main circuit of the thyristor auxiliary module M2 are connected with the dynamic contact Q2 and the public endpoint, respectively.

In the specific implementation process, the control switches KA1 and KA2 are mounted on the rotary shaft, and when the control switches KA1 and KA2 rotate with the rotary shaft, two concentric circles can be drawn respectively, which are respectively called: the third track and the fourth track. A static contact W3 is provided on the third track in a region between the center line of the first static contact on the first track and the center line of the second static contact on the first track, and a static contact W4 is provided on the fourth track in this region. Similarly, the static contacts W3 and W4 repeatedly appear respectively on the third track and the fourth track in a region between the center line of the second static contact on the first track and the center line of the third static contact on the first track, as shown in FIG. 4.

When the control switch KA1 rotates with the rotary shaft and meets the static contact W3, the control switch KA1 closes; when it leaves the static contact W3, the control switch KA1 is broken. When the control switch KA2 rotates with the rotary shaft and meets the static contact W4, the control switch KA2 closes; when it leaves the static contact W4, the control switch KA2 is broken. It can be seen that the static contact W3 and the static contact W4 may not necessarily be made of metal materials, they only need to be able to touch the control switch KA1 to close or the control switch KA2 to close.

When the rotary shaft rotates clockwise, before the dynamic contact J3 leaves the static contact W1, the control switch KA1 must contact the static contact W3; after the dynamic contact J3 leaves the static contact W1, the control switch KA1 is allowed to leave the static contact W3; before the dynamic contact J3 contacts another static contact W1, the control switch KA2 must contact the static contact W4; after the dynamic contact J3 contacts another static contact W1, the control switch KA2 is allowed to leave the static contact W4; and, the control switch KA2 is allowed to contact the static contact W4 at least after the time interval t1 after the control switch KA1 leaves the static contact W3.

When the rotary shaft rotates counter clockwise, before the dynamic contact J3 leaves the static contact W1, the control switch KA2 must contact the static contact W4; after the dynamic contact J3 leaves the static contact W1, the control switch KA2 is allowed to leave the static contact W4; before the dynamic contact J3 contacts another static contact W1, the control switch KA1 must contact the static contact W3; after the dynamic contact J3 contacts another static contact W1, the control switch KA1 is allowed to leave the static contact W3; and, the control switch KA1 is allowed to contact the static contact W3 at least after the time interval t1 after the control switch KA2 leaves the static contact W4.

In order to ensure that the time interval t1 is greater than the set time (e.g. 0.015 seconds), the rotary shaft should not rotate too fast. If the rotary shaft takes T seconds to make one revolution, then:

$$T > ( ( 0.015 \times 2 π ) / ( W 2 - W 3 - W 4 ) ) ,$$

wherein, W2 is the radian of each the static contact on the second track, W3 and W4 are the radians of each static contact on the third track and the radians of each static contact on the fourth track respectively.

In the present embodiment, there is also a control mechanism on the rotary shaft. When the rotary shaft rotates clockwise and before the KA1 leaves the static contact W3, the control mechanism must open the control switch KB1 and close the control switch KB2. When the rotary shaft rotates counterclockwise and before the KA2 leaves the static contact W3, the control mechanism must close the control switch KB1 and open the control switch KB2.

The principle of the switching control of the no-arc on-load tap changer of the present embodiment is as follows:
controlling the rotation of the rotary shaft to drive the dynamic contacts to be connected with or detached from the corresponding static contacts; and
controlling corresponding main switches, change-over switches, and control switch to be broken and closed according to the preset time sequence, to realize that the load current is transferred from an originally-closed main switch to a to-be-closed main switch without interruption, and no arc in the breaking and closing processes of each of the switches.

Wherein, a rotation mode of the rotation of the rotary shaft includes a clockwise rotation and a counterclockwise rotation.

A one-time switching process of main switch of the present embodiment includes:
dynamic contacts of corresponding one of the two change-over switches contact with corresponding static contacts to close a first control switch of the thyristor auxiliary module connected with the originally-closed main switch, and breaking the originally-closed main switch;
closing a second control switch of the thyristor auxiliary module connected to the to-be-closed main switch and breaking the first control switch of the thyristor auxiliary module connected to the originally-closed main switch;
after a set time interval, closing a first control switch of the thyristor auxiliary module connected with the to-be-closed main switch, and closing the to-be-closed main switch; and
breaking all the control switches, and the dynamic contacts of the corresponding one of the two change-over switches are detached from the corresponding static contacts to complete the one-time switching of main switch.

Referring to FIG. 2, the one-time switching process of main switch in the present embodiment is as follows:
(1) contacting the dynamic contacts Q1 and Q2 respectively with the two static contacts W2; closing the control switch KA of the thyristor auxiliary module connected in parallel with the originally-closed main switch;
(2) breaking the originally-closed main switch;
(3) closing the control switch KB of another thyristor auxiliary module connected in parallel with the to-be-closed main switch;
(4) breaking the control switch KA of the thyristor auxiliary module connected in parallel with the originally-closed main switch;
(5) after the time interval t1 (wherein, the time interval t1 is greater than 0.015 seconds), closing the control switch KA of the thyristor auxiliary module in parallel with the to-be-closed main switch over a;
(6) closing the to-be-closed main switch;
(7) breaking all the control switches of the thyristor auxiliary modules;
(8) detaching the dynamic contacts Q1 and Q2 from the static contacts W2; and
(9) completing the one-time switching of main switch.

Referring to FIG. 2, the one-time switching process of main switch of the present embodiment is described by rotating the rotary shaft clockwise and counterclockwise respectively.

The switching control process when the no-arc on-load tap changer of the present embodiment rotates clockwise is as follows:
(1) the dynamic contact J3 rotates clockwise from the center line position of the static contact W1 that has been contacted, the dynamic contact Q1 contacts the static contact W2 connected to the static contact W1 that has been contacted by the dynamic contact J3, and the dynamic contact Q2 contacts the static contact W2 connected to the static contact W1 that will be contacted by the dynamic contact J3. The control switch KA1 of the thyristor auxiliary module M1 contacts the static contact W3, and the control switch KA1 closes. The flow path of the load current is unchanged, and still from the static contact W1 that has been contacted by the dynamic contact J3 flows into the public endpoint through the dynamic contact J3;
(2) the dynamic contact J3 is detached from the static contact W1; the load current flows into the public endpoint from the static contact W2 connected with the original static contact W1, the dynamic contact Q1, and the thyristor auxiliary module M1;
(3) the control switch KB2 of the thyristor auxiliary module M2 closes; the circulation path of the load current remains unchanged;
(4) the control switch KA1 of the thyristor auxiliary module M1 is detached from the static contact W3, and the control switch KA1 is broken. Each zero crossing point of the load current contacts the thyristor auxiliary module M2 once, so that the load current flows into the public endpoint from the static contact W2 connected by the static contact W1 to be contacted, the dynamic contact Q2 and the thyristor auxiliary module M2;
(5) after the time interval t1, the control switch KA2 of the thyristor auxiliary module M2 contacts the static contact W4, and the control switch KA2 closes; the circulation path of the load current remains unchanged;
(6) the dynamic contact J3 contacts the static contact W1 to be contacted; the load current flows from the static contact W1 contacted by the dynamic contact J3, through the dynamic contact J3, into the public endpoint;
(7) the dynamic contacts Q1 and Q2 are detached from the static contacts W2; the control switch KA2 of the thyristor auxiliary module M2 is detached from the static contact W4, the control switch KA2 is broken; the control switch KB2 of the thyristor auxiliary module M2 is broken; and
(8) the dynamic contact J3 rotates to the center line position of the static contact W1 newly contacted and stops rotating; the one-time switching of main switch is completed. The time interval t1 is greater than 0.015 seconds.

The switching control process when the no-arc on-load tap changer of the present embodiment rotates counterclockwise is as follows:
(1) the dynamic contact J3 starts to rotate counterclockwise from the center line position of the static contact W1 that has been contacted. The dynamic contact Q2 contacts the static contact W2 connected to the static contact W1 that has been contacted by the dynamic contact J3, and the dynamic contact Q1 contacts the static contact W2 connected to the static contact W1 that will be contacted by the dynamic contact J3. The control switch KA2 of the thyristor auxiliary module M2 contacts the static contact W4, and the control switch KA2 closes. The flow path of the load current is unchanged, and still from the static contact W1 that has been contacted by the dynamic contact J3 flows into the public endpoint through the dynamic contact J3;
(2) the dynamic contact J3 is detached from the static contact W1; The load current flows into the public endpoint from the static contact W2 connected with the original static contact W1, the dynamic contact Q2, and the thyristor auxiliary module M2;
(3) the control switch KB2 of the thyristor auxiliary module M1 closes; the circulation path of the load current remains unchanged;
(4) the control switch KA2 of the thyristor auxiliary module M2 is detached from W4, and the control switch KA2 is broken. Each zero crossing point of the load current contacts the thyristor auxiliary module M1 once, so that the load current flows into the public endpoint from the static contact W2 connected by the static contact W1 to be contacted, the dynamic contact Q1 and the thyristor auxiliary module M1;
(5) after the time interval t1, the control switch KA1 of the thyristor auxiliary module M1 contacts the static contact W3, and the control switch KA1 closes; the circulation path of the load current remains unchanged;
(6) the dynamic contact J3 contacts the static contact W1 to be contacted; the load current flows from the static contact W1 contacted by the dynamic contact J3, through the dynamic contact J3, into the public endpoint;
(7) the dynamic contacts Q1 and Q2 are detached from the static contacts W2; the control switch KA1 of the thyristor auxiliary module M1 is detached from the static contact W3, the control switch KA1 is broken; the control switch KB1 of the thyristor auxiliary module M1 is broken; and
(8) the dynamic contact J3 rotates to the center line position of the static contact W1 newly contacted and stops rotating; the one-time switching of main switch is completed.

Both the no-arc on-load tap changer of the present embodiment and the existing oil-immersed on-load tap changer use a rotary shaft as driving power, and various switches and contacts can be operated in the oil tank of the oil-immersed transformer. Therefore, the no-arc on-load tap changer of the present invention can be reformed on the basis of the basic structure of the existing oil-immersed on-load tap changer.

The driving force of the existing oil-immersed on-load tap changer comes from an AC motor. In order to prevent the switch switching process from being interrupted due to power loss, the existing on-load tap changer has a spring release mechanism, and if the switch switching process loses power, the spring release mechanism can ensure that the on-load tap changer has a complete switching process. However, the spring energy storage time is longer, and the spring energy storage is carried out only after receiving the switching instruction, and the complete switching process of the existing on-load tap changer is longer. The structure of spring energy storage mechanism and spring energy release mechanism of on-load tap changer is complex, the operation vibration is large, and the failure rate is high.

The no-arc on-load tap changer of the present embodiment can be driven by a DC motor and electrically stored, and the no-arc on-load tap changer can eliminate the spring energy storage mechanism and the spring energy release mechanism.

It should be noted here that the driving motor of the oil-immersed on-load tap changer of the present embodiment may be a DC motor. AC power supply originally supplying power to AC motor supplies power to DC motor through bridge rectifier circuit and voltage stabilizing circuit, output of bridge rectifier circuit is connected in parallel with capacitor energy storage circuit, and stored electric energy of capacitor energy storage circuit can at least provide on-load tap changer to complete one complete operation. The electrical energy storage can be performed before the switching command is received, so that the time of a complete switching process of the no-arc on-load tap changer of the present embodiment is relatively short. Thus, the spring energy storage mechanism and the spring energy release mechanism of the no-arc on-load tap changer of the present embodiment can be eliminated.

The no-arc on-load tap changer of the present embodiment cancels the transition resistance, and there is no heating device in the switching process. In this way, the switching process does not have to have a fast mechanism (ensuring that the transition resistance is energized for no more than 40 milliseconds) as in the existing on-load tap changer. The switching process of the no-arc on-load tap changer of the present embodiment can be completed in tens of seconds. Therefore, the no-arc on-load tap changer of the present invention can be reformed on the basis of the basic structure of the existing oil-immersed non-excitation tap changer.

The no-arc on-load tap changer of the present embodiment has simple structure, small operation vibration and low failure rate. The no-arc on-load tap changer with the structure shown in FIG. 2 is a compound no-arc on-load tap changer. The compound no-arc on-load tap changer mixes the selector and the switcher together, simplifies the on-load tap changer structure, and has low cost; however, it can only be used in situations where the selector is relatively simple. If the on-load tap changer selector is complex and is not suitable for making a composite on-load tap changer, a combined structure of a selector and a switch in series can be adopted. Reducing the first track static contact of the structure of FIG. 2 to two is actually a switch structure. By connecting the switch with this structure in series with the existing selector, a combined no-arc on-load tap changer can be constructed.

### Embodiment 2

The present embodiment provides a no-arc on-load tap changer, and a structure thereof is the same as that of Embodiment 1. The difference is that in the present embodiment, a mechanical linkage mechanism is used to control the control switches KB1 and KB2.

As shown in FIG. 5, the mechanical linkage mechanism of the present embodiment includes a deflection shaft 6, wherein the deflection shaft 6 is fixed on a rotary shaft 4 and rotates along with the rotary shaft 4; a lever arm 7 and a spring arm 8 which can rotate around the deflection shaft 6 are mounted on the deflection shaft 6; a first end of the spring arm 8 is provided with a contact, and the contact contacts with or detaches from the corresponding control switch along with the rotation of the rotary shaft 4, so that the corresponding control switch is broken and closed.

Wherein, the working process of the mechanical linkage mechanism of the present embodiment is as follows:
the rotary shaft 4 can drive a fixed plate 5 to rotate, the fixed plate 5 is further provided with the deflection shaft 6, the deflection shaft is provided with the lever arm 7 and the spring arm 8, the lever arm 7 and the spring arm 8 can rotate around the deflection shaft 6, and the first end of the spring arm 8 is provided with the contact; a circular hoop with the rotary shaft 4 as the center is provided on a stationary insulating frame, gaps on the circular hoop at positions of center lines of the static contacts W1 divide the circular hoop into several sections, and a number of the gaps on the circular hoop correspond to the number of static contacts W1; for example, three static contacts W1 correspond to three the gaps on the circular hoop, and the three gaps divide the circular hoop into a first circular hoop 9 and a second circular hoop 10; and the normal operation state before the switching of the first-type no-arc on-load tap changer is: the lever arm 7 is positioned on a center line of one the gap of the circular hoop.

When the rotary shaft 4 rotates clockwise, the lever arm 7 encounters the second circular hoop 10, the second circular hoop 10 pushes the lever arm 7 to rotate counterclockwise around the deflection shaft 6, the lever arm 7 drives the spring arm 8 to rotate counterclockwise, the contact on the spring arm 8 contacts the contact of the switch KB2, and the switch KB2 closes. Until the lever arm 7 leaves the second hoop 10 and encounters another gap, the lever arm 7 returns to the center line of the gap; the spring arm 8 also returns to the center line of the gap, the contact on the spring arm 8 leaves the contact of the switch KB2, and the switch KB2 is broken.

When the rotary shaft 4 rotates counterclockwise, the lever arm 7 encounters the first circular hoop 9, the first circular hoop 9 pushes the lever arm 7 to rotate clockwise around the deflection shaft 6, the lever arm 7 drives the spring arm 8 to rotate clockwise, the contact on the spring arm 8 contacts the contact of the switch KB1, and the switch KB1 closes. Until the lever arm 7 leaves the first circular hoop 9 and encounters another gap, the lever arm 7 returns to the center line of the gap, the spring arm 8 also returns to the center line of the gap, the contact on the spring arm 8 leaves the contact of the switch KB1, and the switch KB1 is broken.

It can be understood here that a person skilled in the art can specifically design the structure of the mechanical linkage mechanism according to the actual situation, which is not described in detail here.

It should be noted that the switching control process of the no-arc on-load tap changer of the present embodiment is the same as the switching control process of the no-arc on-load tap changer of Embodiment 1, and is not repeated here.

### Embodiment 3

The present embodiment provides a no-arc on-load tap changer, and a structure thereof is the same as that of Embodiment 1. The difference is that the control means for controlling the control switches KB1 and KB2 in the present embodiment is realized by driving change-over switches by the rotary shaft.

In “Electrical Mechanism of On-Load Tap Changer”, edited by Zhu Yinghao et al., published by China Electric Power Press, 2012, p 63-66, it has introduced that a change-over switch MTF driven by rotary shaft can constitute the control switches KB1 and KB2. Four static contacts of the change-over switch MTF in this book are MTF1, MTF2, MTF3 and MTF4 respectively; and, the change-over switch can be switched between two states: (1) the first contact and the third contact are conductive, and the second contact and the fourth contact are disconnected; (2) the first contact and the third contact are disconnected, and the second contact and the fourth contact are conductive. Contacts MTF1 and MTF3 can be used as both ends of control switch KB1, respectively; and contacts MTF2, MTF4 can be used as both ends of control switch KB2, respectively.

It should be pointed out that the change-over switch MTF introduced in “ElectricalMechanism of On-load Tap Changer” is a switch for high current, and the control switches KB1 and KB2 are the switches for small current. Therefore, it is necessary to reduce the size according to the working principle of change-over switch MTF to realize the function of control switches KB1 and KB2. Detailed analysis, no longer repeated here.

It should be noted that the switching control process of the no-arc on-load tap changer of the present embodiment is the same as the switching control process of the no-arc on-load tap changer of Embodiment 1, and is not repeated here.

### Embodiment 4

FIG. 2 shows a no-arc on-load tap changer, wherein the radians of the static contacts are relatively large and the radians of the dynamic contacts are relatively small. It can be seen that the size of the radians of the contacts is to control the length of time and contact sequence that the static contacts contact the dynamic contacts.

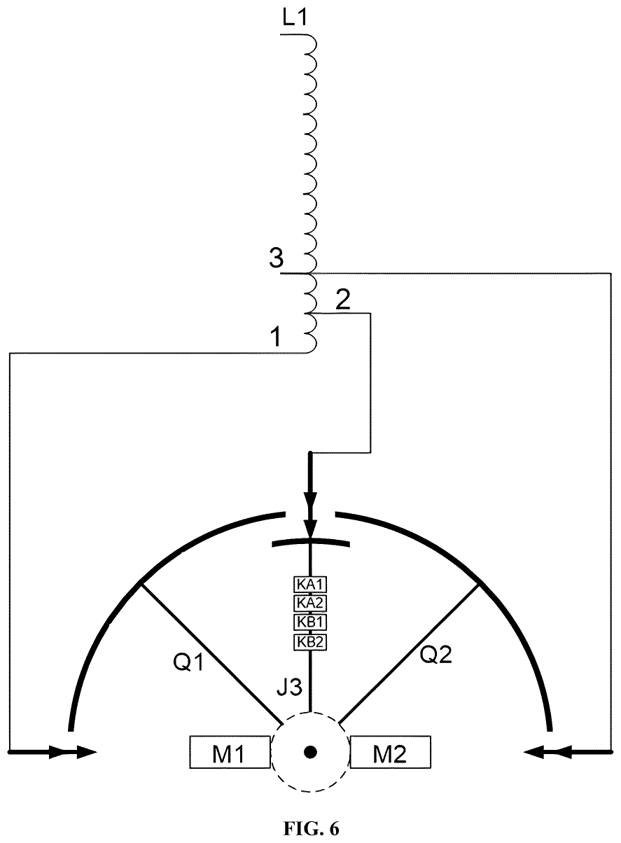

The difference between the present embodiment and Embodiment 1 is that the radians of the static contacts are reduced and the radians of the dynamic contacts are increased, as shown in FIG. 6.

The structure of the rotary shaft of the no-arc on-load tap changer of the present embodiment is shown in FIG. 6. In the present embodiment, there are three static contacts on the first track, and the three static contacts are arranged in sequence; the radian of the gap between the center positions of the first and second static contacts on the first track is equal to W, and the radian of the gap between the center positions of the second and third static contacts on the first track is also equal to W; there are also static contacts on the second track, and the number of the static contacts on the second track is equal to the number of the static contacts on the first track; the center line of each of the static contacts on the first track overlaps with the center line of each of the static contacts on the second track respectively, and the one of the static contacts on the first track and the one of the static contacts on the second track that with the overlapped center line are connected and further connected with three taps of the transformer coil L1 respectively in turn.

The rotary shaft of the embodiment is provided with at least three dynamic contacts: the dynamic contact J3, the dynamic contact Q1 and the dynamic contact Q2; the dynamic contacts are mounted on the rotary shaft and rotates along with the rotary shaft; when the dynamic contact J3 rotates along with the rotary shaft, the dynamic contact J3 is respectively connected with the three static contacts on the first track in sequence; when the dynamic contact Q1 and the dynamic contact Q2 rotate along with the rotary shaft, the dynamic contact Q1 and the dynamic contact Q2 are respectively connected with the three static contacts on the second track in sequence; the center position of the dynamic contact Q1 is on the second track on the left side of the center position of the dynamic contact J3, and the included angle between two the center positions is0.5 W; and the center position of the dynamic contact Q2 is on the second track on the right side of the center position of the dynamic contact J3, and the included angle between two the center positions is 0.5 W.

The radian of the contact of the dynamic contact J3 is W_{1dynamic}, the radians of the contacts of the dynamic contact Q1 and the dynamic contact Q2 are W_{2dynamic}, and the radian of the gap between the dynamic contact Q1 and the dynamic contact Q2 is ΔW_{dynamic}=(W−W_{2dynamic}). Let: 0<ΔW<W_{1dynamic}<0.5 W<W_{2dynamic}, as shown in FIG. 6; wherein, W W′ is the radian between the center positions of each of the static contacts on the first track.

It should also be noted that the breaking and closing of the control switches in the present embodiment is controlled by the control mechanism. The control mechanism may be implemented by using the second embodiment or the third embodiment or other existing control mechanisms, and a person skilled in the art may specifically select the control mechanism according to the actual situation, which is not repeated here.

The switching control method of the no-arc on-load tap changer of the present embodiment is the same as that of the no-arc on-load tap changer of Embodiment 1, and is not repeated here. The no-arc on-load tap changer of the present embodiment has the same contents as the no-arc on-load tap changer of Embodiment 1, and is not repeated here.

By comparing FIG. 2 with FIG. 6, the radians of the static contacts of the first track and the second track of the no-arc on-load tap changer of the present embodiment are relatively small, and the radians of the dynamic contacts are relatively large; because there are only three dynamic contacts, the number of static contacts may be large, so the manufacturing cost of the no-arc on-load tap changer of the present embodiment is lower than that of the no-arc on-load tap changer of Embodiment 1

### Embodiment 5

The present embodiment provides a no-arc on-load tap changer, which include sat least two main switches, two change-over switches and two thyristor auxiliary modules; wherein, each of the two thyristor auxiliary modules includes two control switches; the two main switches comprise an originally-closed main switch and a to-be-closed main switch; the two main switches are connected in corresponding loops of a voltage regulating coil through corresponding transformer taps; the two thyristor auxiliary modules are connected with the originally-closed main switch or the to-be-closed main switch according to a required time sequence during the switching of main switch; and
the two main switches and the two change-over switches are all rotary-shaft-type switches, wherein the two main switches and corresponding one of the two change-over switches are linked and synchronously rotated, respectively; corresponding main switches, change-over switches, and control switches are controlled to be broken and closed according to the preset time sequence, to realize that the load current is transferred from the originally-closed main switch to the to-be-closed main switch without interruption, and no arc in the breaking and closing process of each of the switches.

It should be noted here that the control mechanism is a mechanical linkage mechanism and the structure thereof may adopt the specific structure of the mechanical linkage mechanism described in Embodiment 2, or may adopt the control mechanism described in Embodiment 3. Those skilled in the art can make specific settings according to actual conditions, and will not be described here.

In the present embodiment, the structures of the two thyristor auxiliary modules are the same, and the specific structure thereof is shown in FIG. 1, and the specific description is the same as that of Embodiment 1, so it is not repeated here.

The switching control method of the no-arc on-load tap changer of the present embodiment includes:
controlling breakings and closings of the corresponding main switches and change-over switches by linking and synchronously rotating; and
controlling corresponding main switches, change-over switches, and control switch to be broken and closed according to the preset time sequence, to realize that the load current is transferred from an originally-closed main switch to a to-be-closed main switch without interruption, and no arc in the breaking and closing processes of each of the switches.

### <Electrical Accessory>

In one or more embodiments, providing an electric accessory, including:
a voltage regulating coil, including a plurality of transformer taps; and
a no-arc on-load tap changer, being connected to the voltage regulating coil;
wherein the no-arc on-load tap changer is the no-arc on-load tap changers described in any one of the above Embodiments 1 to 5.

The transformer in the present embodiment is an oil-immersed transformer or a transformer with an oil-immersed vacuum on-load tap changer.

The electric accessory can be constructed in any manner according to requirements, for example as a compensation choke for influencing reactive power in an alternating power grid or as a local power grid transformer or power transformer or adjustable transformer or phase-shifting transformer or rectifier transformer or reactive power compensation device; and/or configured such that the device includes at least one or no additional regulating winding and/or at least one or no additional no-arc on-load tap changer and/or at least one mains winding.

One of the proposed methods can be implemented, for example, with each of the proposed on-load tap changers and each of the proposed devices.

Preferably, each on-load tap changer of the proposed no-arc on-load tap changer can be configured and/or used and/or adapted such that each no-arc on-load tap changer of the proposed no-arc on-load tap changer implements and/or can implement one of the proposed methods. Preferably, each of the proposed devices may be configured and/or used and/or adapted such that each of the proposed devices implements and/or may implement one of the proposed methods.

The foregoing descriptions are merely preferred embodiments of the present invention but are not intended to limit the present invention. A person skilled in art may make various alterations and variations to the present invention. Any modification, equivalent replacement, or improvement made within the spirit and principle of the present invention shall fall within the protection scope of the present invention.

1.-29. (canceled)

30. A no-arc on-load tap changer, comprising at least two main switches, two change-over switches and two thyristor auxiliary modules; wherein, each of the two thyristor auxiliary modules comprises two control switches; the two main switches comprise an originally-closed main switch and a to-be-closed main switch; the two main switches are connected in corresponding loops of a voltage regulating coil through taps of corresponding transformers; the two thyristor auxiliary modules are connected in parallel with the originally-closed main switch or the to-be-closed main switch according to a required time sequence during a switching process of main switch; wherein
the two main switches and the two change-over switches are all rotary-shaft-type switches, dynamic contacts of the two main switches and dynamic contacts of the two change-over switches are all arranged on a rotary shaft, static contacts respectively corresponding to the two main switches and the two change-over switches are connected to the taps of the corresponding transformers, and the dynamic contacts are connected with coaxial static contacts in a process of rotating along with the rotary shaft; wherein, according to a preset time sequence, controlling corresponding ones of the two main switches, corresponding ones of the two change-over switches, and corresponding ones of the control switches to be broken and closed, to realize that a load current is transferred from the originally-closed main switch to the to-be-closed main switch without interruption, and no arc in an breaking and closing process of each of the two main switches, the two change-over switches, and the control switches.

31. The no-arc on-load tap changer according to claim 30, wherein a first end of the each of the two thyristor auxiliary modules is suspended or connected in parallel with the originally-closed main switch before carrying out the switching process of main switch, and a voltage at both ends of the each of the two thyristor auxiliary modules is zero;
each of the control switches is also the rotary-shaft-type switch, and dynamic contacts of the control switches are also arranged on the rotary shaft.

32. The no-arc on-load tap changer according to claim 30, wherein all the static contacts of the two main switches and the two change-over switches are divided into at least two groups, each of the two groups of the static contacts is correspondingly mounted on a track, and the two tracks are centered on the rotary shaft and fixed.

33. The no-arc on-load tap changer according to claim 32, wherein a number of the static contacts in the each of the two groups of the static contacts is same; and
the static contacts in the each of the two groups of the static contacts are mounted on the two tracks with equal radians; wherein
when all the static contacts of the two main switches and the two change-over switches are divided into the two groups, relationships of radians of the static contacts on corresponding one of the two tracks are:
$$\begin{matrix}0 < Δ W < W 1 < 0.5 W < W 2 , \\ Δ W = ( W - W 2 ) ,\end{matrix}$$
wherein, W and W1 respectively are radians between center positions of the static contacts and radians of the static contacts on a first track of the two tracks, W2 and ΔW respectively are radians of the static contacts and radians of gaps between the static contacts on a second track of the two tracks.

34. The no-arc on-load tap changer according to claim 30, wherein before the switching process of main switch, a normal operating state of the no-arc on-load tap changer, comprising:
one of the dynamic contacts on the rotary shaft is located on a center line of one of the static contacts, and remaining the dynamic contacts are respectively located on center lines of gaps between the static contacts.

35. The no-arc on-load tap changer according to claim 34, wherein when three the dynamic contacts are provided on the rotary shaft, a first dynamic contact of the three dynamic contacts and a second dynamic contact of the three dynamic contacts respectively are arranged on each side of a third dynamic contact of the three dynamic contacts, then relationships of radians between the three dynamic contacts are: Error! Digit expected.
$$\begin{matrix}Δ = ( W - W 4 ) \\ 0 < Δ W < {W}_{1 dynamic} < 0.5 W < {W}_{2 dynamic} \\ Δ {W}_{dynamic} = ( W - {W}_{2 dynamic} )\end{matrix}$$
wherein, W is the radian between the center positions of the static contacts on a first track, W_{1dynamic} and W_{2dynamic} respectively are the radians of the first dynamic contact and the second dynamic contact, ΔW_{dynamic} is the radian of the gap between the first dynamic contact and the second dynamic contact.

36. The no-arc on-load tap changer according to claim 30, wherein a breaking and closing of the control switches is controlled by a control mechanism; wherein
the control mechanism is a mechanical linkage mechanism, comprising:
a deflection shaft, the deflection shaft is fixed on the rotary shaft and rotates along with the rotary shaft, a lever arm and a spring arm rotating around the deflection shaft are mounted on the deflection shaft, one end of the spring arm is provided with a contact, and the contact rotates along with the rotary shaft to contact with or detach from corresponding one of the control switches, make the corresponding one of the control switches open or close, respectively;
a control means for the control mechanism is realized by driving the change-over switches by the rotary shaft.

37. The no-arc on-load tap changer according to claim 30, wherein a structure of each of the two thyristor auxiliary modules is same; and
the same structure of the each of the two thyristor auxiliary modules comprises a pair of thyristors connected in reverse parallel; an RC series circuit is connected in parallel at two ends of the pair of the thyristors; a capacitor, a resistor and a diode are sequentially connected between a gate electrode and a cathode of each of the pair of the thyristors; an anode of the diode is connected with the cathode of corresponding one of the pair of the thyristors, and a cathode of the diode is connected with the gate electrode of the corresponding one of the pair of the thyristors; the gate electrodes of the pair of the thyristors are connected in series with one of the two control switches through a full-bridge rectifier circuit; two voltage-stabilizing tubes, a resistor, and another one of the two control switches are connected in series between the gate electrodes of the pair of the thyristors; wherein the two voltage-stabilizing tubes are connected in reverse series, the two voltage-stabilizing tubes are connected in series with the resistor and then connected with an output end of the full-bridge rectifier circuit, cathodes of the two voltage-stabilizing tubes corresponds to an anode output end of the full-bridge rectifier circuit, and anodes of the two voltage-stabilizing tubes corresponds to a cathode output end of the full-bridge rectifier circuit.

38. A switching control method for the no-arc on-load tap changer according to claim 30, and the switching control method comprising:
controlling a rotation of the rotary shaft to drive the dynamic contacts to be connected with or detached from corresponding ones of the static contacts;
controlling corresponding ones of the main switches, corresponding ones of the change-over switches, and corresponding ones of the control switches to be broken and closed according to the preset time sequence, to realize that the load current is transferred from the originally-closed main switch to the to-be-closed main switch without interruption, and no arc in the breaking and closing processes of all the switches.

39. The switching control method for the no-arc on-load tap changer according to claim 38, wherein a rotation mode of the rotation of the rotary shaft comprises a clockwise rotation and a counterclockwise rotation;
a process of one-time switching of main switch, comprising:
dynamic contacts of corresponding one of the two change-over switches contact with corresponding static contacts to close a first control switch of the thyristor auxiliary module connected with the originally-closed main switch, and breaking the originally-closed main switch;
closing a second control switch of the thyristor auxiliary module connected to the to-be-closed main switch and breaking the first control switch of the thyristor auxiliary module connected to the originally-closed main switch;
after a set time interval, closing a first control switch of the thyristor auxiliary module connected with the to-be-closed main switch, and closing the to-be-closed main switch; and
breaking all the control switches, and the dynamic contacts of the corresponding one of the two change-over switches are detached from the corresponding static contacts to complete the one-time switching of main switch; wherein
before the switching of main switch, the voltages between the two ends of the each of the two thyristor auxiliary modules are zero.

40. A no-arc on-load tap changer, comprising at least two main switches, two change-over switches and two thyristor auxiliary modules; wherein, each of the two thyristor auxiliary modules comprises two control switches; the two main switches comprise an originally-closed main switch and a to-be-closed main switch; the two main switches are connected in corresponding loops of a voltage regulating coil through corresponding transformer taps; the two thyristor auxiliary modules are connected with the originally-closed main switch or the to-be-closed main switch according to a required time sequence during a switching process of main switch; wherein,
the two main switches and the two change-over switches are all rotary-shaft-type switches, wherein the two main switches and corresponding one of the two change-over switches are linked and synchronously rotated, respectively; corresponding main switches, change-over switches, and control switches are controlled to be broken and closed according to the preset time sequence, to realize that a load current is transferred from the originally-closed main switch to the to-be-closed main switch without interruption, and no arc in the breaking and closing process of each of the switches.

41. The no-arc on-load tap changer according to claim 40, wherein a breaking and closing of the control switches is controlled by a control mechanism; wherein
the control mechanism is a mechanical linkage mechanism, comprising:
a deflection shaft, wherein the deflection shaft is fixed on a rotary shaft and rotates along with the rotary shaft; a lever arm and a spring arm which can rotate around the deflection shaft are mounted on the deflection shaft; one end of the spring arm is provided with a contact; and the contact makes contact with or detach from corresponding one of the control switches along with rotation of the rotary shaft, so that the corresponding one of the control switches is broken or closed;
a control means for the control mechanism is realized by driving the change-over switches by the rotary shaft.

42. The no-arc on-load tap changer according to claim 40, wherein a structure of each of the two thyristor auxiliary modules is same;
the same structure of the each of the two thyristor auxiliary modules comprises a pair of thyristors connected in reverse parallel; an RC series circuit is connected in parallel at two ends of the pair of the thyristors; a capacitor, a resistor and a diode are sequentially connected between a gate electrode and a cathode of each thyristor of the pair of the thyristors; an anode of the diode is connected with the cathode of corresponding one of the pair of the thyristors, and a cathode of the diode is connected with the gate electrode of the corresponding one of the pair of the thyristors; the gate electrodes of the pair of the thyristors are connected in series with one of the two control switches through a full-bridge rectifier circuit; two voltage-stabilizing tubes, a resistor, and another one of the two control switches are connected in series between the gate electrodes of the pair of the thyristors; wherein the two voltage-stabilizing tubes are connected in reverse series, the two voltage-stabilizing tubes are connected in series with the resistor and then connected with an output end of the full-bridge rectifier circuit, cathodes of the two voltage-stabilizing tubes corresponds to an anode output end of the full-bridge rectifier circuit, and anodes of the two voltage-stabilizing tubes corresponds to a cathode output end of the full-bridge rectifier circuit.

43. A switching control method for the no-arc on-load tap changer according to claim 40, and the switching control method comprising:
controlling a rotation of the rotary shaft to drive the dynamic contacts to be connected with or detached from corresponding ones of the static contacts;
controlling corresponding ones of the main switches, corresponding ones of the change-over switches, and corresponding ones of the control switches to be broken and closed according to the preset time sequence, to realize that the load current is transferred from the originally-closed main switch to the to-be-closed main switch without interruption, and no arc in the breaking and closing processes of all the switches.

44. An electric accessory, comprising:
a voltage regulating coil, including a plurality of transformer taps; and
the no-arc on-load tap changer according to claim 30, being connected to the voltage regulating coil.

45. An electric accessory, comprising:
a voltage regulating coil, including a plurality of transformer taps; and
the no-arc on-load tap changer according to claim 40, being connected to the voltage regulating coil.
